(19) United States
(12) Patent Application Publication
(10) Pub. No.: US 2022/0230855 A1
(43) Pub. Date: Jul. 21, 2022

(54) PROCESS APPARATUS AND PROCESS METHOD

(71) Applicant: CHANGXIN MEMORY TECHNOLOGIES, INC., Hefei City (CN)

(72) Inventor: Ke MA, Hefei City, MA (US)

(21) Appl. No.: 17/452,630

(22) Filed: Oct. 28, 2021

Related U.S. Application Data
(63) Continuation of application No. PCT/CN2021/113173, filed on Aug. 18, 2021.

(30) Foreign Application Priority Data
Jan. 19, 2021 (CN) 202110068749.X

(51) Int. Cl. H01J 37/32; H01L 21/02; C23C 16/44

(52) U.S. Cl. CPC H01J 37/32862; H01J 37/3244; H01J 2237/335; C23C 16/4405; H01L 21/02068

(57) ABSTRACT

The embodiments of the present application provide a process apparatus and a process method, wherein the process apparatus includes: a reaction chamber configured to perform surface treatment processes on a wafer placed in the reaction chamber, the surface treatment processes being used to remove a polluted layer on the surface of the wafer; and a stage located in the reaction chamber and configured to carry the wafer or a carrying plate. The reaction chamber has a first inlet pipe and a second inlet pipe; the first inlet pipe is configured to introduce a reaction gas into the reaction chamber, the reaction gas is used to perform the surface treatment processes; the second inlet pipe is configured to introduce a cleaning gas into the reaction chamber between two surface treatment processes, and the cleaning gas is used to clean the reaction chamber.

### CROSS-REFERENCE TO RELATED APPLICATIONS

This application is a continuation application of International Patent Application No. PCT/CN2021/113173, filed on Aug. 18, 2021, which claims priority to Chinese Patent Application No. 202110068749.X, filed with the Chinese Patent Office on Jan. 19, 2021 and entitled “PROCESS APPARATUS AND PROCESS METHOD.” International Patent Application No. PCT/CN2021/113173 and Chinese Patent Application No. 202110068749.X are incorporated herein by reference in their entireties.

### TECHNICAL FIELD

The present application relates to the field of semiconductor processes, and in particular to a process apparatus and a process method.

### BACKGROUND

Aluminum has been widely used as the material for metal connecting wires in the semiconductor industry due to its advantages such as low resistivity, easy availability or the like. With a gradual reduction in the integrated circuit size and an increase in the designed aspect ratio, it is imperative to realize smaller chip size and thinner metal connecting wires.

Aluminum metal wires are featured by their comparatively poor electron migration resistance. During the existing processes, a barrier layer is generally deposited between aluminum metal and a medium layer to prevent the diffusion of aluminum. Since the complicated manufacturing processes often cause the surface of the medium layer to be oxidized and polluted, oxidative pollutants on the surface of the medium layer are removed before the barrier layer is deposited on the surface of the medium layer.

The applicant has found that while the oxidative pollutants on the surface of the medium layer is continuously removed by a machine, the state of a chamber inside the machine will deteriorate, and there rises a problem that the pollutants inside the chamber fall off to affect the yield of products. How to improve the state of the chamber inside the machine while the machine continuously removes the oxidative pollutants on the surface of the medium layer is a problem that needs to be solved urgently.

### SUMMARY

The embodiments of the present application provide a process apparatus and a process method, aiming at improving the state of the chamber inside the machine while the machine continuously removes the oxidative pollutants on the surface of the medium layer and thus increasing the yield of wafer products.

The embodiments of the present application provide a process apparatus, which includes: a reaction chamber configured to perform surface treatment processes on a wafer placed in the reaction chamber, the surface treatment processes being used to remove a polluted layer on the surface of the wafer; and a stage located in the reaction chamber and configured to carry the wafer or a carrying plate. The reaction chamber has a first inlet pipe and a second inlet pipe; the first inlet pipe is configured to introduce a reaction gas into the reaction chamber, the reaction gas is used to perform the surface treatment process; the second inlet pipe is configured to introduce a cleaning gas into the reaction chamber between two surface treatment processes, and the cleaning gas is used to clean the reaction chamber.

The embodiments of the present application also provide a process method, which, based on the above process apparatus, includes: placing a carrying plate on a stage of the process apparatus between two surface treatment processes performed by the process apparatus; controlling a second inlet pipe to introduce a cleaning gas into a reaction chamber and controlling a first inlet pipe to introduce a reaction gas into the reaction chamber, the cleaning gas being used to clean the reaction chamber; and taking out the carrying plate on the stage to finish cleaning the reaction chamber.

### BRIEF DESCRIPTION OF DRAWINGS

The exemplary descriptions of one or more embodiments are made by using the corresponding drawings. Unless otherwise stated, the figures in the accompanying drawings do not constitute a scale limitation.

FIG. 1 to FIG. 4 are schematic structural diagrams of a semiconductor structure corresponding to various steps in an aluminum metal connecting wire deposition procedure according to an embodiment of the present application.

FIG. 5 to FIG. 6 are schematic structural diagrams of a process apparatus according to an embodiment of the present application.

FIG. 7 is a schematic flow chart of a process method between two surface treatment processes according to another embodiment of the present application.

FIG. 8 to FIG. 12 are schematic structural diagrams of a process apparatus corresponding to various steps of the process method between two surface treatment processes according to another embodiment of the present application.

FIG. 13 is a schematic flow chart of a process method for a single surface treatment process according to another embodiment of the present application.

FIG. 14 and FIG. 15 are schematic structural diagrams of the process apparatus corresponding to various steps of the process method for a single surface treatment process according to another embodiment of the present application.

### DESCRIPTION OF EMBODIMENTS

Referring to FIG. 1, a semiconductor structure includes a substrate 101 and a medium layer 102. Through holes are formed in the substrate 101 and the medium layer 102. Formed in the through hole are a first conductive film 103 that is located on a sidewall of the through hole and a second conductive film 104 that fills the through hole, wherein the second conductive film 104 is made of a tungsten material. It is to be noted that the semiconductor structure according to the present embodiment is merely for description of the problems in the related art, and does not constitute a limitation to the present embodiment.

With continued reference to FIG. 1, the complicated manufacturing processes often cause the surface of the medium layer 102 to be oxidized and polluted to finally create an oxide layer 110, i.e., the oxide layer 110 located at the top of the semiconductor structure. Therefore, the oxide layer 110 needs to be removed when the aluminum metal wire is deposited on the semiconductor structure, avoiding the situation where the formed aluminum metal wire is unable to be electrically connected with the second conductive film 104 owing to the presence of the oxide layer 110.

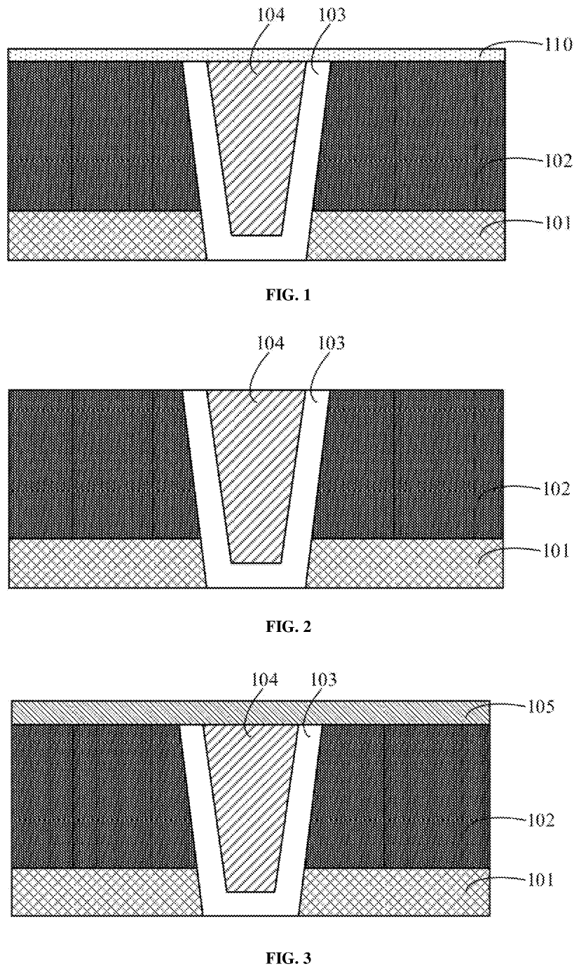

Referring to FIG. 2, the semiconductor structure with the oxide layer 110 at its top is placed in the semiconductor process apparatus to finish removing the oxide layer 110.

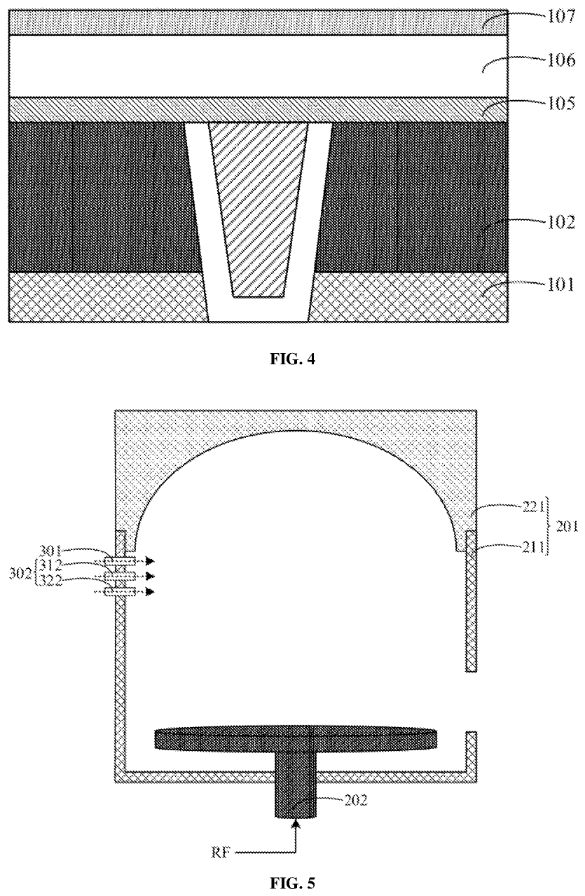

With reference to FIG. 3 and FIG. 4, a first conductive layer 105, a second conductive layer 106 and a third conductive layer 107 are sequentially deposited at the top of the semiconductor structure, wherein the material of the second conductive layer 106 is aluminum, which has been widely used as the material for metal connecting wires in the semiconductor industry due to its advantages such as low resistivity, easy availability or the like; the material of the first conductive layer 105 is titanium, which is featured by excellent electron migration resistance and therefore can prevent diffusion of metal ions in the second conductive layer 106; and the material of the third conductive layer 107 is titanium nitride, which is used for electrical connection of the second conductive layer 106 with the subsequently-formed semiconductor conductive materials.

It has been mentioned in the foregoing process that the oxide layer needs to be removed when the metal wire is deposited on the semiconductor structure, and that while the oxidative pollutants on the surface of the medium layer are continuously removed by a machine, the state of a chamber inside the machine will deteriorate, and there rises a problem that the pollutants inside the chamber fall off to affect the yield of products.

An embodiment of the present application provides a process apparatus, which includes: a reaction chamber configured to perform surface treatment processes on a wafer placed in the reaction chamber, the surface treatment processes being used to remove a polluted layer on the surface of the wafer; and a stage located in the reaction chamber and configured to carry the wafer or a carrying plate. The reaction chamber has a first inlet pipe and a second inlet pipe; the first inlet pipe is configured to introduce a reaction gas into the reaction chamber, the reaction gas is used to perform the surface treatment process; the second inlet pipe is configured to introduce a cleaning gas into the reaction chamber between two surface treatment processes, and the cleaning gas is used to clean the reaction chamber.

In order to make the objects, the technical solutions, and the advantages of the embodiments of the present application clearer, the detailed description of the embodiments of the present application is given below in combination with the accompanying drawings. However, the ordinary skills in the art can understand that many technical details are provided in the embodiments of the present application so as to make the readers better understand the present application. However, even if these technical details are not provided and based on a variety of variations and modifications of the following embodiments, the technical solutions sought for protection in the present application can also be realized. The following embodiments are divided for convenience of description, and should not constitute any limitation to the implementation of the present application. The embodiments may be combined with each other and referred to each other without contradiction.

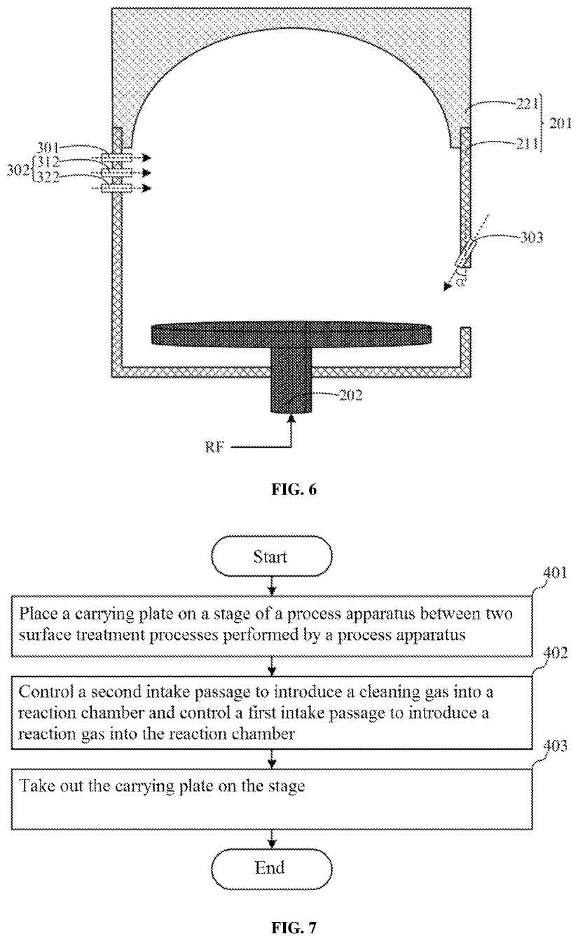

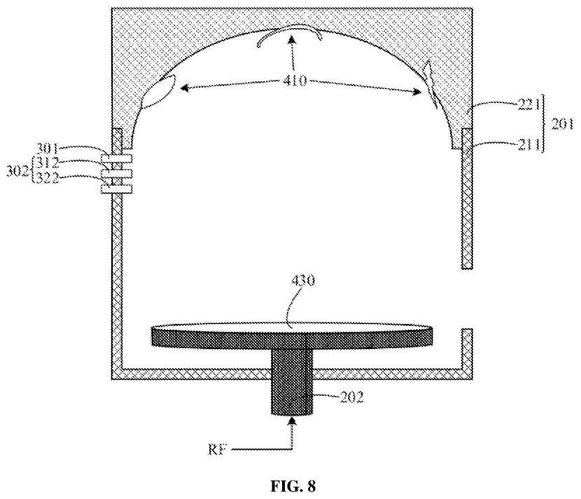

FIG. 5 and FIG. 6 are schematic structural diagrams of a process apparatus according to the present embodiment. The process apparatus according to the embodiments of the present application will be described in details below with reference to the accompanying drawings: referring to FIG. 5, the process apparatus includes: a reaction chamber 201 configured to perform surface treatment processes on a wafer placed in the reaction chamber 201, the surface treatment processes being used to remove a polluted layer on the surface of the wafer.

In an example, the reaction chamber 201 includes a bottom chamber 211 and a top cover 221, interior spaces of the bottom chamber 211 and the top cover 221 constitute the reaction chamber 201, an access valve is disposed at the bottom of the bottom chamber 211 and configured to put a wafer and a carrying plate into the reaction chamber 201 or take the wafer and the carrying plate out of the reaction chamber 201.

A stage 202 located in the reaction chamber 201 and configured to carry the wafer or the carrying plate.

In an example, the stage 202 is located at the bottom of the bottom chamber 211, the stage 202 is connected with a radio frequency power source configured to cause the surface of the stage 202 to be positively charged or negatively charged.

The reaction chamber 201 has a first inlet pipe 301 and a second inlet pipe 302; the first inlet pipe 301 is configured to introduce a reaction gas into the reaction chamber 201, the reaction gas is used to perform the surface treatment process; the second inlet pipe 302 is configured to introduce a cleaning gas into the reaction chamber 201 between two surface treatment processes, and the cleaning gas is used to clean the reaction chamber 201.

In an example, the reaction gas is plasma argon, i.e., Ar+; the plasma argon may be directly introduced into the reaction chamber 201 through the first inlet pipe 301 after being formed outside, or alternatively, an argon gas may be introduced into the reaction chamber 201 and then converted into the plasma argon in the reaction chamber 201, with the equation for conversion being: Ar+e−=Ar++2e−; after the radio frequency power source causes the surface of the stage 202 to be negatively charged, the positively charged Ar+moves towards the direction of the stage 202 and performs physical bombardment upon the wafer carried by the stage 202, so as to finish the surface treatment processes for the wafer; the negatively charged e-moves away from the direction of the stage 202, namely a large number of electrons are gathered in the top cover 221 to convert the introduced argon gas into the plasma argon. It shall be noted that the fact mentioned in the present embodiment that the reaction gas is the plasma argon is merely for description of the performance of the surface treatment processes in the present embodiment, and does not constitute a limitation to the present embodiment. In other embodiments, other types of plasmas may also be employed to finish the surface treatment processes for the wafer on the stage.

The surface treatment process for the wafer is based upon physical bombardment, i.e., after the oxide layer at the top of the semiconductor structure (see FIG. 1) is removed, the material of the oxide layer remains in the reaction chamber 201. For this reason, the state of a chamber inside a machine will deteriorate while the oxidative pollutants on the surface of the medium layer 102 (see FIG. 1) are continuously removed by the process apparatus, there rises a problem that the pollutants inside the chamber fall off, and the fallen pollutants fall on the surface of the wafer to create gaps in the formed first, second and third conductive layers 105, 106 and 107, affecting the yield of products.

In the present embodiment, the second inlet pipe 302 is configured to introduce a cleaning gas into the reaction chamber 201 between two surface treatment processes, and the cleaning gas is used to clean the reaction chamber 201.

In particular, the cleaning gas includes a reducing gas and a first purge gas, the second inlet pipe 302 includes a first inlet subpipe 312 and a second inlet subpipe 322; wherein the first inlet subpipe 312 is configured to introduce the reducing gas into the reaction chamber 201, and the second inlet subpipe 322 is configured to introduce the first purge gas into the reaction chamber 201.

More specifically, between two surface treatment processes, the carrying plate is placed on the stage 202, the reducing gas is introduced into the reaction chamber 201 through the first inlet subpipe 312 and undergoes a redox reaction with the oxidative pollutants adhered inside the reaction chamber 201, such that a degree of adhesion of the pollutants adhered to the reaction chamber 201 is reduced; then, the reaction gas is introduced into the reaction chamber through the first inlet pipe 301 and at this moment, bombards the pollutants adhered to the reaction chamber 201 to cause the solid pollutants to fall off onto the carrying plate; finally, the first purge gas is introduced into the reaction chamber 201 through the second inlet subpipe 322 to finish purging the reaction chamber 201, and in the meantime, the carrying plate on the stage 202 is moved out of the reaction chamber 201, so as to finish cleaning the reaction chamber 201 between two surface treatment processes. In the present embodiment, the reducing gas at least includes a hydrogen gas, and the first purge gas at least includes one of a nitrogen gas and an inert gas.

In the present embodiment, the process apparatus further includes a first gas supply module connected with the first inlet pipe 301, an opening time of the first gas supply module is 10 to 15 s, and a flow rate at which the reaction gas is introduced is 4 to 6 sccm/s. In an example, the opening time of the first gas supply module is 12 s or 14 s, the flow rate at which the reaction gas is introduced is 5 sccm/s. If the opening time of the first gas supply module is shorter than 10 s, it is impossible to introduce sufficient reducing gas into the reaction chamber 201, such that the reaction between the reducing gas and the pollutants adhered to the reaction chamber 201 is not complete enough and thus the cleaning condition of the reaction chamber 201 is affected; if the opening time of the first gas supply module is longer than 15 s, it means that an interval between two surface treatment processes is extended, which accordingly lowers an efficiency of the surface treatment processes; if the flow rate of the reducing gas is less than 4 sccm/s, it is impossible to introduce sufficient reducing gas into the reaction chamber 201, such that the reaction between the reducing gas and the pollutants adhered to the reaction chamber 201 is not complete enough and thus the cleaning condition of the reaction chamber 201 is affected; and if the flow rate of the reducing gas is greater than 6 sccm/s, an excessive amount of reducing gas is introduced, thereby causing a waste of resources and raising the process cost for cleaning of the reaction chamber.

In the present embodiment, the process apparatus further includes a second gas supply module connected with the first inlet subpipe 312, the opening time of the second gas supply module is 25 to 40 s, and the flow rate at which the reaction gas is introduced is 6 to 10 sccm/s. In an example, the opening time of the second gas supply module is 30 s or 35 s, the flow rate at which the reducing gas is introduced is 8 sccm/s. If the opening time of the second gas supply module is shorter than 25 s, it is impossible to introduce sufficient reaction gas into the reaction chamber 201, such that the reaction gas cannot fully bombard the pollutants adhered to the reaction chamber 201 and thus the cleaning condition of the reaction chamber 201 is affected; if the opening time of the second gas supply module is longer than 40 s, it means that the interval between two surface treatment processes is extended, which accordingly lowers the efficiency of the surface treatment processes; if the flow rate of the reaction gas is less than 6 sccm/s, it is impossible to introduce sufficient reaction gas into the reaction chamber 201, such that the reaction gas cannot fully bombard the pollutants adhered to the reaction chamber 201 and thus the cleaning condition of the reaction chamber 201 is affected; and if the flow rate of the reaction gas is greater than 10 sccm/s, an excessive amount of reaction gas is introduced, thereby causing a waste of resources and raising the process cost for cleaning of the reaction chamber.

In the present embodiment, the process apparatus further includes a third gas supply module connected with the second inlet subpipe 322, the opening time of the third gas supply module is 6 to 10 s, and the flow rate at which the first purge gas is introduced is 6 to 10 sccm/s. In an example, the opening time of the third gas supply module is 7 s or 9 s, the flow rate at which the first purge gas is introduced is 8 sccm/s. If the opening time of the third gas supply module is shorter than 6 s, it is impossible to completely purge the remaining gas in the reaction chamber 201, such that the cleaning gas may be present in the reaction chamber and affect the subsequent surface treatment process; if the opening time of the third gas supply module is longer than 10 s, it means that the interval between two surface treatment processes is extended, which accordingly lowers the efficiency of the surface treatment processes; if the flow rate of the first purge gas is less than 6 sccm/s, it is impossible to completely purge the remaining gas in the reaction chamber 201, such that the cleaning gas may be present in the reaction chamber and affect the subsequent surface treatment process; and if the flow rate of the first purge gas is greater than 10 sccm/s, an excessive amount of first purge gas is introduced, thereby causing a waste of resources and raising the process cost for cleaning of the reaction chamber.

In an example, the process apparatus further includes a control module in which a first preset time, a second preset time and a third preset time are stored; the control module is configured to: open the first inlet subpipe 312 to introduce the reducing gas into the reaction chamber 201 for the first preset time; close the first inlet subpipe 312 and open the first inlet pipe 301 to introduce the reaction gas into the reaction chamber 201 for the second preset time; and close the first inlet pipe 301 and open the second inlet subpipe 322 to introduce the first purge gas into the reaction chamber for the third preset time. Cleaning of the reaction chamber is accomplished through automation of the control module, thus avoiding that the yield of products is decreased due to human manipulation errors and further increasing the yield of products. The first preset time is an introduction time for the reducing gas, the second preset time is an introduction time for the reaction gas, and the third preset time is an introduction time for the first purge gas.

Referring to FIG. 6, in the present embodiment, the reaction chamber 201 further has a third inlet pipe 303. While the wafer is removed from the reaction chamber after the surface treatment processes are finished, the third inlet pipe is configured to purge the surface of the wafer with a second purge gas. While the wafer is taken out of the reaction chamber, the surface of the wafer is continuously purged through the third inlet pipe 303. The pollutants can still be purged with the second purge gas even if they fall onto the surface of the wafer, and by doing so, the yield of wafer products is further guaranteed. In the present embodiment, the second purge gas at least includes one of the nitrogen gas and the inert gas.

In particular, the third inlet pipe 303 is disposed on the access valve of the reaction chamber 201, and an included angle between a gas inlet of the third inlet pipe 303 and a cavity wall of the reaction chamber 201 is 5° to 35°. Based on the included angle of 5° to 35°, the purging effect of the second purge gas for the surface of the wafer is better. In an example, the included angle between the gas inlet of the third inlet pipe 303 and the cavity wall of the reaction chamber 201 is 10°, 20°, or 30°.

In the present embodiment, the process apparatus further includes a fourth gas supply module connected with the third inlet pipe 303, the opening time of the fourth gas supply module is 4 to 6 s, and the flow rate at which the second purge gas is introduced is 3 to 6 sccm/s. In an example, the opening time of the fourth gas supply module is 5 s, the flow rate at which the second purge gas is introduced is 4sccm/s or 5 sccm/s. If the opening time of the fourth gas supply module is shorter than 4 s, the time for the second purge gas to purge the surface of the wafer cannot cover the procedure in which the wafer is taken out of the reaction chamber 201, and all-around purging for the surface of the wafer cannot be guaranteed; if the opening time of the fourth gas supply module is longer than 6 s, the fourth gas supply module, after the wafer is taken out of the reaction chamber 201, still keeps on gas supply, so as to cause a waste of resources and raise the cost for purging of the surface of the wafer; if the flow rate of the second purge gas is less than 3 sccm/s, then a flow velocity of the gas is too small to purge and remove the pollutants on the surface of the wafer; and if the flow rate of the second purge gas is greater than 6 sccm/s, then the flow velocity of the gas is too large and there is a tremendous amount of gas supplied within a same purging time, thereby causing a waste of resources and raising the cost for purging of the surface of the wafer.

Compared with the related art, the process apparatus is added with the second inlet pipe configured to introduce the cleaning gas into the reaction chamber between two surface treatment processes, the cleaning gas is used to clean the pollutants inside the reaction chamber, so cleaning for the reaction chamber is completed between the two surface treatment processes performed by the process apparatus, which ensures that the reaction chamber is clean when the surface treatment processes are performed on the wafer and further avoids the problem that the yield of products is affected by falling off of the pollutants.

Another embodiment of the present application relates to a process method, which, based on the process apparatus according to the above-mentioned embodiment, includes: placing a carrying plate on a stage of the process apparatus between two surface treatment processes performed by the process apparatus; controlling a second inlet pipe to introduce a cleaning gas into a reaction chamber and controlling a first inlet pipe to introduce a reaction gas into the reaction chamber, the cleaning gas being used to clean the reaction chamber; and taking out the carrying plate on the stage to finish cleaning the reaction chamber.

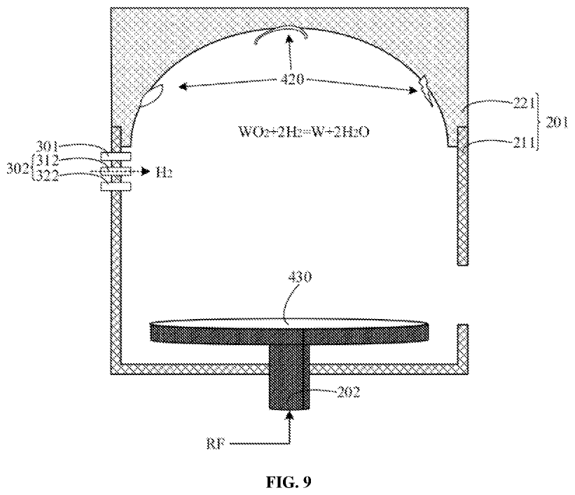

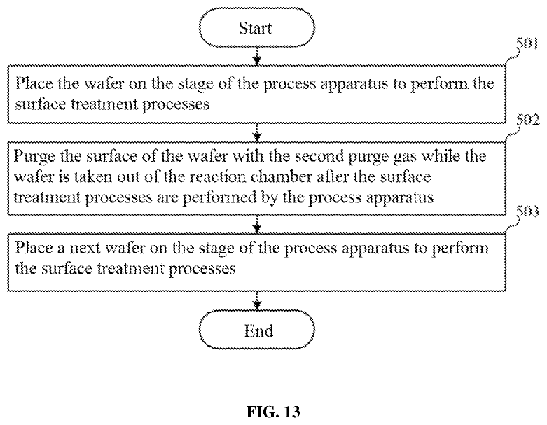

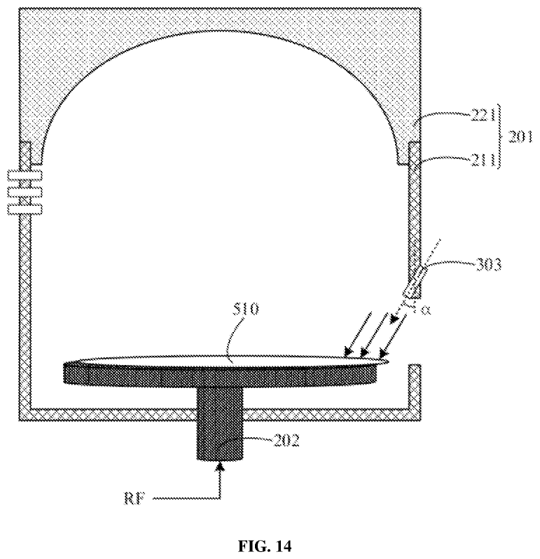

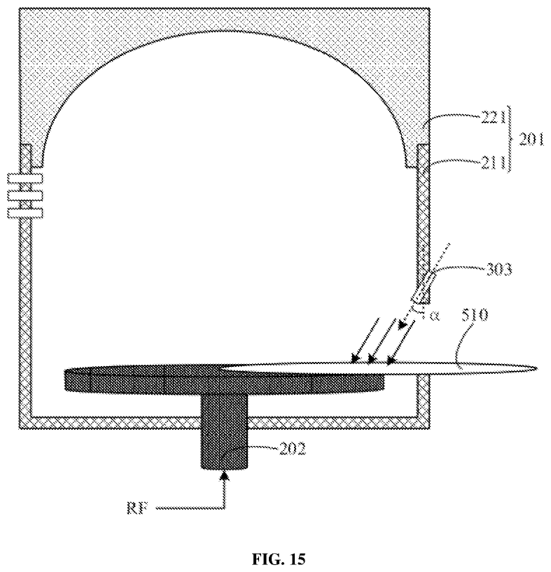

FIG. 7 is a schematic flow chart of a process method between two surface treatment processes according to the present embodiment, FIG. 8 to FIG. 12 are schematic structural diagrams of a process apparatus corresponding to various steps of the process method between two surface treatment processes according to the present embodiment, FIG. 13 is a schematic flow chart of the process method for a single surface treatment process according to the present embodiment, FIG. 14 and FIG. 15 are schematic structural diagrams of the process apparatus corresponding to various steps of the process method for a single surface treatment process according to the present embodiment, and the process method according to the embodiments of the present application will be described in details below with reference to the accompanying drawings: referring to FIG. 7, the process method includes:
S401: placing a carrying plate on a stage of a process apparatus between two surface treatment processes performed by the process apparatus.

With reference to FIG. 8, there are solid pollutants 410 in the reaction chamber 201. It shall be noted that the solid pollutants in FIG. 8 are merely for detailed description of the pollutants in the reaction chamber 201, and do not constitute a limitation to position and shape. The carrying plate 430 is placed on the stage 202 through the access valve of the reaction chamber 201.

In an example, the carrying plate 430 may be a scrapped wafer with a relatively poor yield that originates from other process flows, and the carrying plate 430 is configured to carry and take out the solid pollutants 410 in the reaction chamber 201.

With continued reference to FIG. 7, S402: controlling a second inlet pipe to introduce a cleaning gas into a reaction chamber and controlling a first inlet pipe to introduce a reaction gas into the reaction chamber, wherein the cleaning gas is used to clean the reaction chamber.

In particular, controlling a second inlet pipe to introduce a cleaning gas into a reaction chamber and controlling a first inlet pipe to introduce a reaction gas into the reaction chamber includes the following steps of: controlling the first inlet subpipe to introduce the reducing gas into the reaction chamber for the first preset time.

Referring to FIG. 9, in the present embodiment, the reducing gas at least includes hydrogen gas; the hydrogen gas is introduced into the reaction chamber 201 through the first inlet subpipe 312 and chemically reacts with the solid pollutants 410 in the reaction chamber 201 to generate the softened pollutants 420, and the reaction equation for the chemical reaction that occurs is WO2+2H2=W+2H2O, wherein the oxidative pollutants are exemplified by tungsten dioxide in the present embodiment, and this does not constitute a limitation to the present embodiment. As compared to the solid pollutants 410 (see FIG. 8), the softened pollutants 420 have a reduced strength of adhesion to the cavity wall of the reaction chamber 201.

In the present embodiment, the first preset time is 25 to 40 s, and the flow rate at which the reducing gas is introduced is 6 to 10 sccm/s. In an example, the first preset time is 30 s or 35 s, the flow rate at which the reducing gas is introduced is 8 sccm/s. If the first preset time is shorter than 25 s, it is impossible to introduce sufficient reaction gas into the reaction chamber 201, such that the reaction gas cannot fully bombard the pollutants adhered to the reaction chamber 201 and thus the cleaning condition of the reaction chamber 201 is affected; if the first preset time is longer than 40 s, it means that the interval between two surface treatment processes is extended, which accordingly lowers the efficiency of the surface treatment processes; if the flow rate of the reaction gas is less than 6 sccm/s, it is impossible to introduce sufficient reaction gas into the reaction chamber 201, such that the reaction gas cannot fully bombard the pollutants adhered to the reaction chamber 201 and thus the cleaning condition of the reaction chamber 201 is affected; and if the flow rate of the reaction gas is greater than 10 sccm/s, an excessive amount of reaction gas is introduced, thereby causing a waste of resources and raising the process cost for cleaning of the reaction chamber.

Controlling the first inlet pipe to introduce the reaction gas into the reaction chamber for the second preset time.

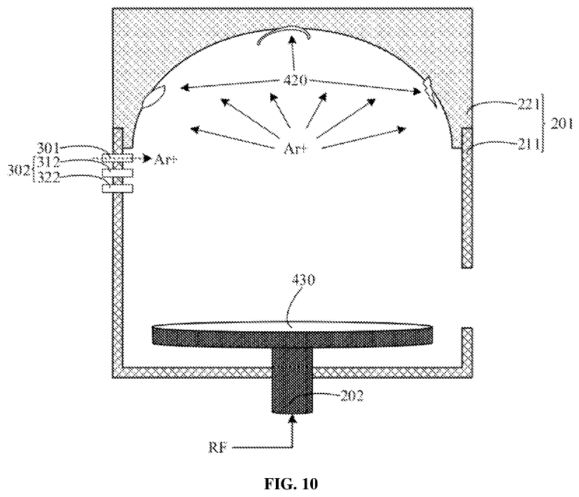

Referring to FIG. 10, the reaction gas is introduced into the reaction chamber 201 through the first inlet pipe 301 and then bombards the softened pollutants 420 adhered to the reaction chamber 201.

In the present embodiment, the second preset time is 10 to 15 s, and the flow rate at which the reaction gas is introduced is 4 to 6 sccm/s. In an example, the second preset time is 12 s or 14 s, and the flow rate at which the reaction gas is introduced is 5 sccm/s. If the second preset time is shorter than 10 s, it is impossible to introduce sufficient reducing gas into the reaction chamber 201, such that the reaction between the reducing gas and the pollutants adhered to the reaction chamber 201 is not complete enough and thus the cleaning condition of the reaction chamber 201 is affected; if the second preset time is longer than 15 s, it means that the interval between two surface treatment processes is extended, which accordingly lowers the efficiency of the surface treatment processes; if the flow rate of the reducing gas is less than 4 sccm/s, it is impossible to introduce sufficient reducing gas into the reaction chamber 201, such that the reaction between the reducing gas and the pollutants adhered to the reaction chamber 201 is not complete enough and thus the cleaning condition of the reaction chamber 201 is affected; and if the flow rate of the reducing gas is greater than 6 sccm/s, an excessive amount of reducing gas is introduced, thereby causing a waste of resources and raising the process cost for cleaning of the reaction chamber.

Controlling the second inlet subpipe to introduce the second purge gas into the reaction chamber for the third preset time.

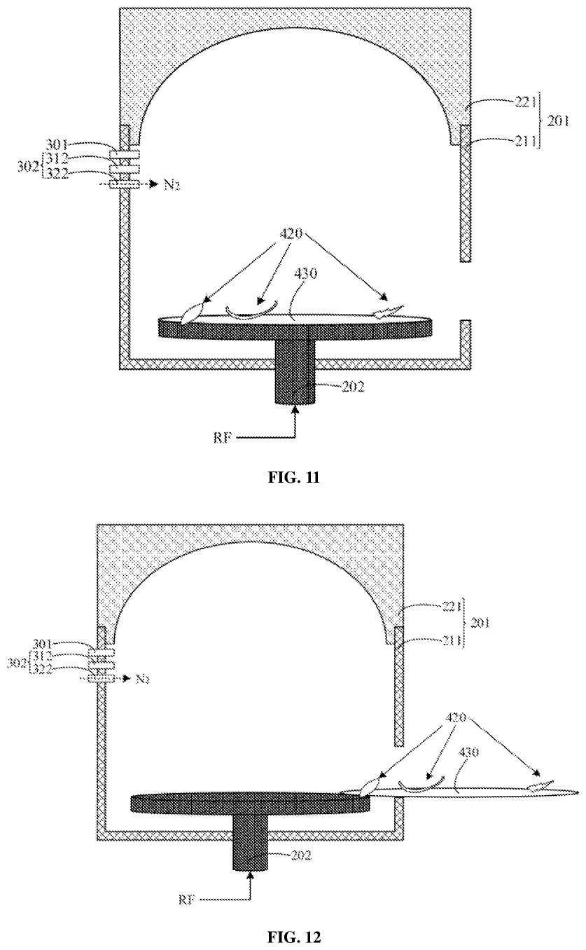

Referring to FIG. 11, in the present embodiment, the first purge gas at least includes one of the nitrogen gas and the inert gas; the softened pollutants 420 that are bombarded by the reaction gas fall onto the carrying plate 430, in which case the first purge gas is continuously introduced into the reaction chamber 201 through the second inlet subpipe 322, in order to finish cleaning the gas environment inside the reaction chamber 201.

In the present embodiment, the third preset time is 6 to 10 s, and the flow rate at which the first purge gas is introduced is 6 to 10 sccm/s. In an example, the third preset time is 7 s or 9 s, and the flow rate at which the first purge gas is introduced is 8 sccm/s. If the third preset time is shorter than 6 s, it is impossible to completely purge the remaining gas in the reaction chamber 201, such that the cleaning gas may be present in the reaction chamber and affect the subsequent surface treatment process; if the third preset time is longer than 10 s, it means that the interval between two surface treatment processes is extended, which accordingly lowers the efficiency of the surface treatment processes; if the flow rate of the first purge gas is less than 6 sccm/s, it is impossible to completely purge the remaining gas in the reaction chamber 201, such that the cleaning gas may be present in the reaction chamber and affect the subsequent surface treatment process; and if the flow rate of the first purge gas is greater than 10 sccm/s, an excessive amount of first purge gas is introduced, thereby causing a waste of resources and raising the process cost for cleaning of the reaction chamber.

S403: taking out the carrying plate on the stage. Cleaning of the reaction chamber is finished after the carrying plate on the stage is removed.

Referring to FIG. 12, the carrying plate 430 carries and moves the fallen softened pollutants 420 out of the reaction chamber 201, so as to realize cleaning of the reaction chamber 201.

While the wafer is taken out of the reaction chamber after the surface treatment processes are performed by the process apparatus, the surface of the wafer is purged with the second purge gas. Referring to FIG. 13, the process method includes: S501: placing the wafer on the stage of the process apparatus to perform the surface treatment processes.

S502: purging the surface of the wafer with the second purge gas while the wafer is taken out of the reaction chamber after the surface treatment processes are performed by the process apparatus.

Referring to FIG. 14 and FIG. 15, while the wafer is taken out of the reaction chamber 201, the surface of the wafer is purged with the second purge gas, and while the wafer is taken out of the reaction chamber 201, the surface of the wafer is continuously purged through the third inlet pipe 303. The pollutants can still be purged with the second purge gas even if they fall onto the surface of the wafer, and by doing so, the yield of wafer products is guaranteed. In the present embodiment, the second purge gas at least includes one of the nitrogen gas and the inert gas.

In the present embodiment, the second purge gas purges the surface of the wafer in a direction that the included angle with respect to a cavity wall of the reaction chamber 201 is 5° to 35°. Based on the included angle of 5° to 35°, the purging effect of the second purge gas for the surface of the wafer is better. In an example, the second purge gas purges the surface of the wafer in a direction that the included angle with respect to the cavity wall of the reaction chamber 201 is 10°, 20°, or 30°.

In the present embodiment, the time for the second purge gas to purge the surface of the wafer is 4 to 6 s, and the flow rate at which the second purge gas is introduced is 3 to 6 sccm/s. In an example, the time for the second purge gas to purge the surface of the wafer is 5 s, and the flow rate at which the second purge gas is introduced is 4 sccm/s or 5 sccm/s. If the time for the second purge gas to purge the surface of the wafer is shorter than 4 s, then the time for the second purge gas to purge the surface of the wafer cannot cover the procedure in which the wafer is taken out of the reaction chamber 201, and all-around purging for the surface of the wafer cannot be guaranteed; if the time for the second purge gas to purge the surface of the wafer is longer than 6 s, the fourth gas supply module, after the wafer is taken out of the reaction chamber 201, still keeps on gas supply, so as to cause a waste of resources and raise the cost for purging of the surface of the wafer; if the flow rate of the second purge gas is less than 3 sccm/s, then the flow velocity of the gas is too small to purge and remove the pollutants on the surface of the wafer; and if the flow rate of the second purge gas is greater than 6 sccm/s, then the flow velocity of the gas is too large and there is a tremendous amount of gas supplied within the same purging time, thereby causing a waste of resources and raising the cost for purging of the surface of the wafer.

S503: placing a next wafer on the stage of the process apparatus to perform the surface treatment processes.

Compared with the related art, cleaning for the reaction chamber is completed between the two surface treatment processes performed by the process apparatus, which ensures that the reaction chamber is clean when the surface treatment processes are performed on the wafer and further avoids the problem that the yield of products is affected by falling off of the pollutants.

The division of the steps above is merely for clarity of description. The steps may be combined to one step or some of the steps may be split to a plurality of steps when being implemented, and all of these fall within the protection scope of the present patent as long as they have a same logic relationship. Adding insignificant modifications to the flow or introducing inessential designs without changing key designs of the flow fall within the protection scope of the patent.

The above embodiment and the present embodiment may be coordinately implemented due to their correspondence. The details of the related art mentioned in the above embodiment are applicable in the present embodiment, and the technical effects achievable in the above embodiment can also be realized in the present embodiment, which are not described here to reduce repetition. Correspondingly, the details of the related art mentioned in the present embodiment are also applicable in the above embodiment.

Those skilled in the art understand that the above embodiments are the specific embodiments for implementing the present application. However, in practical applications, various changes may be made to them in view of form and detail without departing from the spirit and scope of the present application.

What is claimed is:

1. A process apparatus, comprising:
a reaction chamber configured to perform surface treatment processes on a wafer placed in the reaction chamber, the surface treatment processes being used to remove a polluted layer on a surface of the wafer; and
a stage located in the reaction chamber and configured to carry the wafer or a carrying plate;
the reaction chamber having a first inlet pipe and a second inlet pipe;
the first inlet pipe being configured to introduce a reaction gas into the reaction chamber, the reaction gas being configured to perform the surface treatment process;
the second inlet pipe being configured to introduce a cleaning gas into the reaction chamber between the two surface treatment processes, and the cleaning gas being used to clean the reaction chamber.

2. The process apparatus according to claim 1, wherein the cleaning gas further comprises a reducing gas and a first purge gas, the second inlet pipe comprises:
a first inlet subpipe configured to introduce the reducing gas into the reaction chamber; and
a second inlet subpipe configured to introduce the first purge gas into the reaction chamber;
the second inlet pipe being configured to introduce the cleaning gas into the reaction chamber specifically comprises:
the reducing gas being introduced into the reaction chamber through the first inlet subpipe, the reaction gas being introduced into the reaction chamber through the first inlet pipe, and the first purge gas being introduced into the reaction chamber through the second inlet subpipe.

3. The process apparatus according to claim 2, further comprising:
a control module in which a first preset time, a second preset time and a third preset time are stored;
the control module being configured to:
open the first inlet subpipe to introduce the reducing gas into the reaction chamber for the first preset time;
close the first inlet subpipe and open the first inlet pipe to introduce the reaction gas into the reaction chamber for the second preset time; and
close the first inlet pipe and open the second inlet subpipe to introduce the first purge gas into the reaction chamber for the third preset time.

4. The process apparatus according to claim 2, comprising: a first gas supply module connected with the first inlet pipe, an opening time of the first gas supply module being 10 to 15 s, and a flow rate at which the reaction gas is introduced being 4 to 6 sccm/s.

5. The process apparatus according to claim 2, comprising: a second gas supply module connected with the first inlet subpipe, an opening time of the second gas supply module being 25 to 40 s, and a flow rate at which the reducing gas is introduced being 6 to 10 sccm/s.

6. The process apparatus according to claim 2, comprising: a third gas supply module connected with the second inlet subpipe, an opening time of the third gas supply module being 6 to 10 s, and a flow rate at which the first purge gas is introduced being 6 to 10 sccm/s.

7. The process apparatus according to claim 1, wherein the reaction chamber further has a third inlet pipe, and while the wafer is taken out of the reaction chamber after the surface treatment processes are finished, the third inlet pipe is configured to purge the surface of the wafer with a second purge gas.

8. The process apparatus according to claim 7, wherein the third inlet pipe is disposed on an access valve of the reaction chamber, and an included angle between a gas inlet of the third inlet pipe and a cavity wall of the reaction chamber is 5° to 35°.

9. The process apparatus according to claim 7, comprising: a fourth gas supply module connected with the third inlet pipe, an opening time of the fourth gas supply module is 4 to 6 s, and a flow rate at which the second purge gas is introduced is 3 to 6 sccm/s.

10. A process method applied to the process apparatus according to claim 1, comprising:
placing a carrying plate on a stage of the process apparatus between two surface treatment processes performed by the process apparatus;
controlling a second inlet pipe to introduce a cleaning gas into the reaction chamber and controlling a first inlet pipe to introduce a reaction gas into the reaction chamber, the cleaning gas being used to clean the reaction chamber; and
taking out the carrying plate on the stage to finish cleaning the reaction chamber.

11. The process method according to claim 10, wherein the controlling a second inlet pipe to introduce a cleaning gas into the reaction chamber and controlling a first inlet pipe to introduce a reaction gas into the reaction chamber comprises:
controlling a first inlet subpipe to introduce a reducing gas into the reaction chamber for a first preset time;
controlling the first inlet pipe to introduce the reaction gas into the reaction chamber for a second preset time; and
controlling a second inlet subpipe to introduce a first purge gas into the reaction chamber for a third preset time.

12. The process method according to claim 11, wherein the first preset time is 25 to 40 s, and a flow rate at which the reducing gas is introduced is 6 to 10 sccm/s.

13. The process method according to claim 11, wherein the second preset time is 10 to 15 s, and a flow rate at which the reaction gas is introduced is 4 to 6 sccm/s.

14. The process method according to claim 11, wherein the third preset time is 6 to 10 s, and a flow rate at which the first purge gas is introduced is 6 to 10 sccm/s.

15. The process method according to claim 11, wherein the reducing gas at least comprises a hydrogen gas.

16. The process method according to claim 11, wherein the first purge gas at least comprises one of a hydrogen gas or an inert gas.

17. The process method according to claim 10, wherein while the wafer is taken out of the reaction chamber after the surface treatment processes are performed by the process apparatus, the surface of the wafer is purged with a second purge gas.

18. The process method according to claim 17, wherein the second purge gas purges the surface of the wafer in a direction that an included angle with respect to a cavity wall of the reaction chamber is 5° to 35°.

19. The process method according to claim 17, wherein a time for the second purge gas to purge the surface of the wafer is 4 to 6 s, and a flow rate at which the second purge gas is introduced is 3 to 6 sccm/s.

20. The process method according to claim 17, wherein the second purge gas at least comprises one of a hydrogen gas or an inert gas.
